(19) United States
(12) Patent Application Publication
(10) Pub. No.: US 2012/0090659 A1
(43) Pub. Date: Apr. 19, 2012

(54) PORTABLE SOLAR PANEL ARRAY

(75) Inventors: David J. Muchow, Arlington, VA (US); Sara V. Zulkosky, Arlington, VA (US)

(73) Assignee: SKYBUILT POWER, INC.

(21) Appl. No.: 13/276,674

(22) Filed: Oct. 19, 2011

Related U.S. Application Data
(60) Provisional application No. 61/394,548, filed on Oct. 19, 2010.

(51) Int. Cl. H01L 31/045

(52) U.S. Cl. 136/245

(57) ABSTRACT

A portable assembly for supporting a plurality of solar panels may include a plurality of solar panels mechanically coupled to each other and configured to transform from an expanded configuration to a collapsed configuration. Each solar panel of the plurality of solar panels may include one or more solar cells. The expanded configuration may be a configuration in which an active surface of each solar panel of the plurality of solar panels is exposed. And, the collapsed configuration may be a configuration in which the active surfaces of the plurality of solar panels overlap. The portable assembly may also include connectors configured to removably electrically connect the plurality of solar panels together.

### PRIORITY

This application claims the benefit of priority from U.S. Provisional Application No. 61/394,548, filed Oct. 19, 2010, which is herein incorporated by reference in its entirety.

### TECHNICAL FIELD

This disclosure relates generally to a portable solar panel array and a method of using the portable solar panel array.

### BACKGROUND

Solar energy technology is a renewable energy technology that harnesses and uses the sun's energy to provide heat, light, hot water, electricity, and even cooling, for homes, businesses, and industry. Different types of solar collectors are used to harness the sun's energy. One type of solar collector, photovoltaic cells (or solar cells), convert sunlight directly to electricity. Typically, one or more panels (each comprising one or more solar cells arranged thereon) are deployed at a location to convert sunlight to electricity. Despite sunlight's significant potential for supplying energy, solar power provides less than 1% of U.S. energy needs (see Renewable Energy Sources in the United States, available at http://nationalatlas.gov/articles/people/a_energy.html). One of the factors that limits the widespread use of solar energy technology is the cost associated with solar panels.

Conventional solar panels have several shortcomings. For example, conventional solar panels, permanently deployed at a location, produce energy only at times when the panels are illuminated by sunlight. Therefore, these solar panels do not produce energy for a significant portion of their operational life. Further, a defective solar panel in a conventional solar panel installation may be difficult to remove and replace with a new solar panel. The disclosed portable solar panel arrays overcomes one or more of the problems set forth above.

### SUMMARY

In accordance with an embodiment, a portable assembly for supporting a plurality of solar panels is disclosed. The assembly may include a plurality of solar panels mechanically coupled to each other and configured to transform from an expanded configuration to a collapsed configuration. Each solar panel of the plurality of solar panels may include one or more solar cells. The expanded configuration may be a configuration in which an active surface of each solar panel of the plurality of solar panels is exposed. And, the collapsed configuration may be a configuration in which the active surfaces of the plurality of solar panels overlap. The portable assembly may also include connectors configured to removably electrically connect the plurality of solar panels together.

In accordance with a further embodiment, a method of using a portable array of solar panels is disclosed. The portable array may include a plurality of solar panels mechanically coupled to each other. Each solar panel of the plurality of solar panels may include one or more solar cells. The method may include positioning the portable array in an expanded configuration. The expanded configuration may be a configuration in which the plurality of solar panels are arranged side-by-side and an active surface of each solar panel of the plurality of solar panels is exposed. The method may also include transforming the portable array from the expanded configuration to a collapsed configuration. The collapsed configuration may be a configuration in which the plurality of solar panels are stacked over each other while maintaining the mechanical coupling of the panels to one another.

In accordance with another embodiment, A portable assembly for supporting a plurality of solar panels. The assembly may include a plurality of solar panels. Each solar panel of the plurality of solar panels may include one or more solar cells. The plurality of solar panels may include an even number of solar panels mechanically coupled together. The plurality of solar panels may be configured to transform from an expanded configuration to a collapsed configuration. The expanded configuration may be a configuration in which the plurality of solar panels are arranged side-by-side with an active surface of each solar panel exposed. And, the collapsed configuration may be a configuration in which the plurality of solar panels are stacked one on top of another. The assembly may also include connectors that are configured to electrically couple the plurality of solar panels together.

Additional objects and advantages of the invention will be set forth in part in the description which follows, and in part will be obvious from the description, or may be learned by practice of the invention. The objects and advantages of the invention will be realized and attained by means of the elements and combinations particularly pointed out below.

It is to be understood that both the foregoing general description and the following detailed description are exemplary and explanatory only and are not restrictive of the invention.

### BRIEF DESCRIPTION OF THE DRAWINGS

The accompanying drawings, which are incorporated in and constitute a part of this specification, illustrate several embodiments of the invention and together with the description, serve to explain the principles of the embodiments.

FIG. 1A illustrates an exemplary embodiment of a foldable solar panel of the current disclosure in an expanded configuration;

FIG. 1B illustrates the foldable solar panel of FIG. 1A being transformed from an expanded configuration to a collapsed configuration;

FIG. 1C illustrates the foldable solar panel of FIG. 1A in the collapsed configuration;

FIG. 2A illustrates a front view of a portion of the foldable solar panel of FIG. 1A;

FIG. 2B illustrates a back view of the portion of the foldable solar panel of FIG. 2A;

FIG. 3A illustrates a right-most portion of the foldable solar panel of FIG. 1A;

FIG. 3B illustrates the left-most portion of the foldable solar panel of FIG. 1A;

FIG. 4 illustrates another embodiment of the foldable solar panel of FIG. 1A; and

FIG. 5 illustrates another embodiment of the foldable solar panel of FIG. 1A.

### DESCRIPTION OF THE EMBODIMENTS

Reference will now be made in detail to exemplary embodiments of the invention, examples of which are illustrated in the accompanying drawings. Wherever possible, the same reference numbers will be used throughout the drawings to refer to the same or like parts.

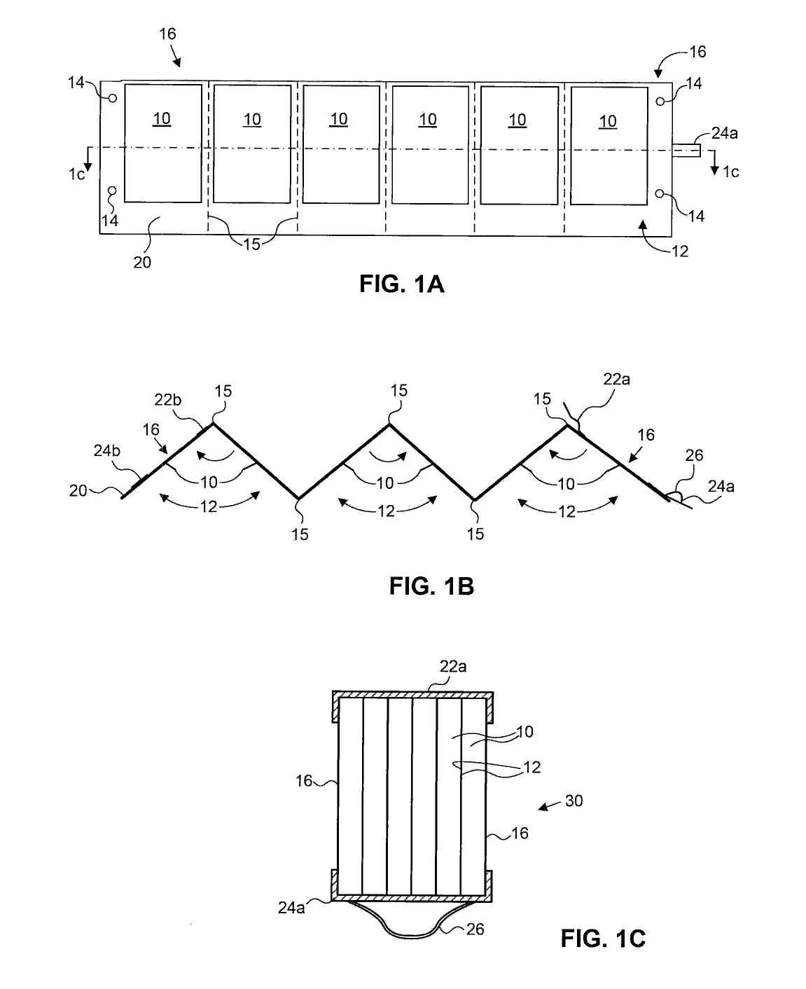

FIGS. 1A-1C illustrate an exemplary embodiment of a foldable solar panel array (foldable array 30) of the current disclosure. Foldable array 30 includes a plurality of solar panels 10 (photovoltaic (PV) cells or solar cells, panels, etc.) that are linked together and configured to be transformed from an expanded configuration to a collapsed configuration. In this disclosure, the term “panel” is used to represent an individual solar cell and a collection of solar cells that are arranged together. FIGS. 1A and 1C illustrate the foldable array 30 in the expanded and the collapsed configuration, respectively, and FIG. 1B illustrates the foldable array 30 being folded from the expanded configuration to the collapsed configuration. In the discussion that follows, reference will be made to FIGS. 1A-1C. Foldable array 30 includes a first face 12 and an opposite second face 16. The active surface (surface that absorb photons from sunlight) of the solar panels 10 may be exposed through the first face 12. In an application, the foldable array 30 may be transformed to the expanded configuration and deployed in a manner such that the first face 12 (with the active surface of the solar panels 10 exposed) is exposed to sunlight. The foldable array 30 may include fastening features to retain and secure the foldable array 30 in the deployed position. Any type of fastening features may be provided for this purpose. In some embodiments, as illustrated in FIG. 1A, holes 14 may be provided to secure the foldable array 30 to the ground. These holes 14 may be reinforced with a non-rusting ring or grommet to avoid tearing. Although four holes 14 are illustrated in FIG. 1A, any number of holes 14 may be provided for this purpose. For instance, more holes may be added to secure larger and/or heavier foldable arrays 30.

To move the foldable array 30 from its current position and deploy it at another location (or store it for future use), the fastening features (such as, holes 14) may be released, and the foldable array 30 folded to the collapsed configuration. Transforming the foldable array 30 to its collapsed configuration may reduce its physical size to enable storage and/or transportation from one place to another. Although the foldable array 30 may be transformed from the expanded configuration to the collapsed configuration in any manner, in some embodiments, as illustrated in FIG. 1B, the foldable array 30 may be folded in an accordion-like manner to its collapsed configuration. In some embodiments (as illustrated in FIGS. 1B and 1C), the foldable array 30 may be folded such that, in the collapsed configuration, the active surfaces of the solar panels (that is, the first face 12 of the foldable array 30) are covered. In some embodiments, the active surfaces of adjacent solar cells may face each other in the collapsed configuration. Covering the active surface of the solar panels 10 may protect the solar panels 10 from damage. However, it is also contemplated that, in some embodiments, the foldable array 30 may be folded such that the first face 12 is exposed in the collapsed configuration.

The foldable array 30 may include mechanisms and/or features (such as, for example, straps 22a, 24a and mating fasteners 22b, 24b, ties, etc.) to secure the foldable array 30 in the collapsed configuration. The foldable array 30 may also include features that serves as a handle that a user can grasp to transport a folded assembly from one place to another. Although any feature can serve as a handle, in some embodiments, a handle may be incorporated with a securement feature (such as, for example, strap 24a of FIG. 1B). Although not illustrated and discussed herein, the foldable array 30 may include other securement features (such as, clips, hooks, anti-skid pads etc.) that may assist in draping and securing the foldable array 30 in a sloping surface (such as, for example, a sloping roof or another sloping or curved surface. In some embodiments, foldable array 30 may also include other features, such as, for example, wheels, etc. to assist in transporting the foldable array 30 from one location to another.

Any number and any type of solar panels 10 may be included in a foldable array 30. In some embodiments, an even number of solar panels 10 may be provided. An even number of solar panels arranged in a configuration as illustrated in FIG. 1A, may ensure that the active surface of all the solar panels 10 are covered in the collapsed configuration. However, this is not a requirement. In some embodiments, the foldable array 30 may include an odd number of solar panels 10, or even a single solar panel 10. In these embodiments, an active surface of some of the solar panels may be exposed in the collapsed configuration. In some such embodiments, a portion of the foldable array 30 (such as for example, excess material provided on a side of the left-most or right-most solar panel 10) may serve as a cover or a flap that covers some or all of the active surface of the exposed solar panel 10 in the collapsed configuration.

Although one row of solar panels 10 is illustrated in FIG. 1A, this is only exemplary. In some embodiments, the solar panels 10 may be arranged as a 2-dimensional matrix array (that is, multiple rows and columns). For example, in an embodiment of foldable array 30 with hundred solar panels 10, the solar panels 10 may be arranged in a matrix array having 10 rows and 10 columns, that is, a 10×10 matrix array. In some embodiments, all the solar panels in an array may be of a similar type (number of solar cells, size of panel, etc.), while in other embodiments, different types of solar panels 10 may be used in a foldable array 30. For example, some of the solar panels 10 in a foldable array 30 may be of a smaller size and include less number of solar cells than other solar panels 10 in the foldable array 30.

The foldable array 30 may be configured to fold from the expanded configuration to the collapsed configuration in any manner. In some embodiments, the foldable array may be made of a flexible sheet 20 (such as, for example, a sheet made of a fabric, tarpaulin, canvas, nylon or plastic-type of material). The flexible sheet 20 may enable the foldable array 30 to be draped on a sloping roof or on the roof of a tent. In some embodiments, sheet 20 may be coated with one or more materials/chemicals to increase its durability and improve its performance in the environment for which the foldable array 30 is designed for. Any type of coating may be applied on the flexible sheet 20. For example, in some embodiments, a neoprene coating may be provided to increase the resistance of sheet 20 to solvents, oils, and UV rays. In some embodiments, a polyurethane coating may be provided to increase its resistance to tears, abrasion, and rot. It is contemplated that, in some embodiments, sheet 20 may be laminated with vinyl or another material to provide water resistance. It is also contemplated that sheet 20 may be treated with other materials to increase its flame resistance and/or covered with a camouflage type laminate or a coating to increase efficiency. In some embodiments, each solar cell within a panel may be laminated separately and arranged together to form a panel 10. It should also be noted that, as explained previously, in some embodiments a panel 10 may include only a single solar cell.

The region of sheet 20 between the individual solar panels 10 may be folded as illustrated in FIG. 1B to collapse the foldable array 30. To improve foldability, in some embodiments, a fold 15 may be defined in the sheet 20 between adjacent solar panels 10. Fold 15 may enable the sheet 20 between the solar panels 10 be folded along a line. Fold 15 may include any mechanism (such as, for example, perforations, live hinge, region of reduced thickness, etc.) that selectively increases the flexibility of the sheet 20 along the fold 15.

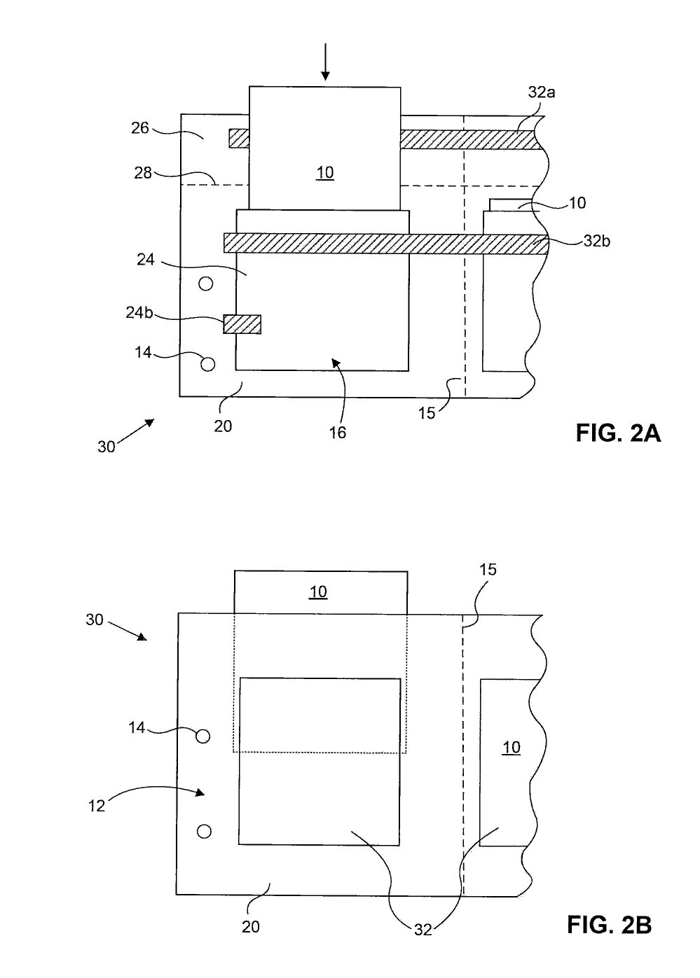

Sheet 20 may include pockets or pouches 24 into which individual solar panels 10 may be inserted. FIGS. 2A and 2B illustrate a section of sheet 20 showing a solar panel 10 being inserted into a pouch 24 formed on its second face 16. FIG. 2A illustrates a view from the second face 16, and FIG. 2B illustrates a view from the first face 12. Pouch 24 be any form of receptacle that is configured to removably contain a solar panel 10 therein. To replace a defective solar panel 10, the solar panel 10 may be electrically decoupled and the panel 10 merely lifted out of the pouch 24 and replaced. In some embodiments, pouch 24 may include a receptacle formed by overlapping layers of the material of sheet 20. Although not a requirement, in some embodiments, the pouch 24 may be sized slightly larger than a solar panel 10 so that the solar panel 10 fits snugly therein. A solar panel 10 may be inserted into a pouch 24 such that the active surface of the solar panel 10 faces the first face 12 of sheet 20. A corresponding region of the pouch 24 on the first face 12 may include a window 32 that exposes the active surface of the solar panel 10 therethrough. Window 32 may be a region of first face 12 with the material of sheet 20 removed so that the solar panel 10 is exposed therethough. The window 32 may be large enough to expose as much of the active surface of a solar panel 10 to sunlight while preventing the solar panel 10 from slipping out through the window 32. It is contemplated that, in some embodiments, a transparent (or even a translucent) layer may be attached to window 32 to allow sunlight to pass therethrough, while securely retaining the solar panel within the pouch 24.

Sheet 20 may include a flap 26 provided in a region above a pouch 24. After a solar panel 10 is inserted into the pouch 24, the flap 26 may be folded along a fold 28 (towards the second face 16) to cover the opening of the pouch 24 and securely contain the solar panel 10 within the pouch 24. Fold 28 may be a region of sheet 20 of increased flexibility that permits the flap 26 to fold along a line formed by the fold 28. In embodiments where the sheet 20 is sufficiently flexible to permit the flap 26 to be folded over the opening of the pouch 26, a separate fold 28 may be eliminated. Attachment strips 32a and 32b may also be provided on second face 16 of sheet 20 to allow the flap 26 to be folded over and attached to back of the pouch 24. Any type of attachment mechanism that allows the flap 26 to be removably attached over the back of the pouch 24 (such as, for example, Velcro strips, strips of sticky material, snap-fit attachment features, etc.) may serve as the attachment strips 32a and 32b. Although the solar panel 10 is described as being inserted into pouch 24, and the flap 26 folded over and attached to back of the pouch 24, to constrain the solar panel 10 therein, this is only exemplary. In general, the solar panels 10 may be positioned in, and constrained in, sheet 20, by any method. For example, in some embodiments, the rear side (side opposite the active surface) of the solar panel 10 may include attachment features (for example, a Velcro strip) that align with, and attach to, a mating attachment feature in the pouch 24 to constrain the solar panel 10 therein. Furthermore, although FIGS. 2A and 2B illustrate the pouch 24 as being formed by a patch of material attached to the second face 16 of the sheet 20, this is only exemplary. In general, the receptacle to contain the solar panels 10 may be formed by any method. For example, in some embodiments, sheet 20 may be formed by two strips of material attached one on top of the other, and the receptacle formed between the two strips may contain the solar panels 10.

In some embodiments, a foldable array 30 may be transformed from the expanded configuration to the collapsed configuration by rolling. That is, in the collapsed configuration the foldable array 30 may resemble a rolled up carpet. To deploy the foldable array 30 at a location, the foldable array 30 may be transported to the location and unrolled and spread out to expose the solar panels 10 to sunlight. After use, the foldable array 30 may be rolled up and easily transported to another location such as by putting the roller in an intermodal shipping container or air cargo container. In some such embodiments, a sheet 20 having a number of solar panels 10 arranged in an array may be attached at one edge to a tube (rod, or other similar element) to facilitate the rolling of the sheet 20. As described with reference to FIGS. 1A and 1B, the sheet 20 may also include handles, wheels, and fastening features to assist in the deployment and transportation of the foldable array 30.

As mentioned previously, any type of solar panel 10 (with any type and number of solar cells) may be used in foldable array 30. These solar panels 10 may have any size. In some embodiments, each solar panel 10 may have a size of approximately 11.5×17×0.25 inches and include an array of solar cells positioned on its front surface (active surface). In some embodiments, the corners of these solar panels 10 may be rounded, and include a backing layer attached to its back surface. Any type of backing material, and any type of attachment medium may be used to attach the backing material to the solar panel 10. Although not a requirement, in some embodiments, the backing material and the attachment medium may be selected so that the solar panels 10 and the backing material do not separate from each other over a temperature range of interest, such as, for example from −40° F. to 140° F. In some embodiments, the backing material may be made of a light-weight plastic-type material. In some embodiments, the backing material may be corrugated. In embodiments where a corrugated backing is used, the attachment medium may be applied around the edges as a seal to prevent dirt and debris from entering the corrugation.

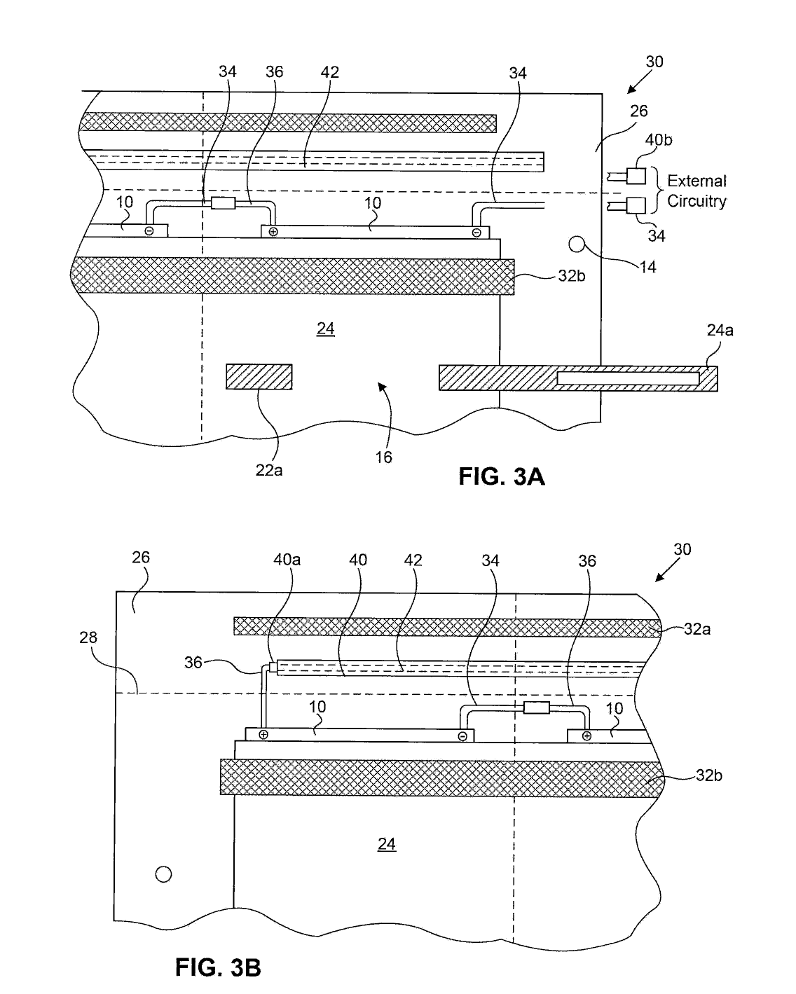

The solar panels 10 may include electrical connectors. Any type of connector known in the art (such as, for example, multi-contact (MC) connectors) may be used with solar panels 10. These connectors may be used to electrically connect the solar panels 10 to external circuitry (device storing or using energy, not shown). FIGS. 3A and 3B illustrate a right-most portion and a left-most portion, respectively, of the second face 16 of the foldable array 30 with electrically connected solar panels 10 positioned in its pouches 24. The connectors of a solar panel 10 may include a positive connector 36 and a negative connector 34. These connectors 34, 36 may be positioned at any location in the solar panel 10. In some embodiments, as illustrated in FIGS. 3A and 3B, the negative connector 34 may be positioned proximate a right corner and the positive connector 36 may be positioned in the left corner of the solar panel 10. In some embodiments, both the negative and the positive connectors 34, 36 may be positioned between the left and the right corners proximate the center. After the solar panels 10 are inserted into the pouches 24, the solar panels 10 are electrically connected together and to the external circuitry. The solar panels 10 may be electrically connected together in any manner known in the art. In some embodiments, as illustrated in FIGS. 3A and 3B, the solar panels 10 are electrically daisy chained together in series. For instance, the positive connector 36 of one solar panel 10 is connected to the negative connector 34 of an adjacent solar panel 10. The free connector (the connector unconnected to an adjacent solar panel 10) may be electrically connected to external circuitry. That is, as illustrated in FIGS. 3A and 3B, the free negative terminal 34 of the right-most solar panel 10 and the free positive terminal 36 of the left-most solar panel 10 may be connected to the external circuitry.

In some embodiments, one or more feed wires 40 may be provided in the sheet 20 to electrically couple the free terminals of one or both of the left-most and right-most solar panels to external circuitry. In the embodiment of FIGS. 3A and 3B, a single feed-wire 40, embedded in the sheet 20 and extending across the width of the foldable array 30, is used to electrically connect the positive terminal 36 of the left-most solar panel 10 to external circuitry. The feed-wire 40 may include connectors 40a and 40b at either end. A connector 40a at one end may couple with the free positive connector 36 of the left-most solar panel 10, and the other connector 40b may connect to the external circuitry. The circuit is completed by connecting the free negative terminal 34 of the right-most solar panel 10 to external circuitry. In some embodiments, multiple feed wires may be embedded in the sheet 20 to electrically connect one or more of the solar panels 10 to external circuitry. For example, both the free terminals of the left-most and the right-most solar panels 10 may be connected to external circuitry through feed-wires embedded in the sheet 20. Although the feed-wire 40 is described as being embedded in sheet 20, this is not a requirement. The feed-wire 40 may be positioned in sheet 20 in any manner. In some embodiments, a channel or a raceway 42 may be formed on the second face 16 of sheet 20 by attaching a strip of material thereto. The feed-wire 40 may extend across the width of the foldable array 30 in the raceway 42. In some embodiments, the feed-wires embedded in the sheet 20 and electrically connected to the free terminals of the solar panels 10 may extend to an electrical socket positioned at a suitable location of the sheet 20. In such an embodiment, a mating connector from the external circuit may be connected to the socket to complete the circuit.

It should be emphasized that the above-described electrical connection technique is only exemplary. In general, the solar panels 10 positioned in the foldable array 30 may be electrically connected to each other and to the external circuitry in any manner. For instance, in some embodiments, positive and negative terminals may extend to an external surface of the solar panels 10. And, mating terminals in the flap 26 (or at another location in sheet 20) may mate with and electrically connect these solar panel 10 terminals to external circuitry (or a common socket) when the flap 26 is folded over the solar panels 10. In such an embodiment, the flap 26 may include the electrical circuitry that connects the adjacent solar panels 10 together and the free terminals of the solar panels 10 at either end to external circuitry.

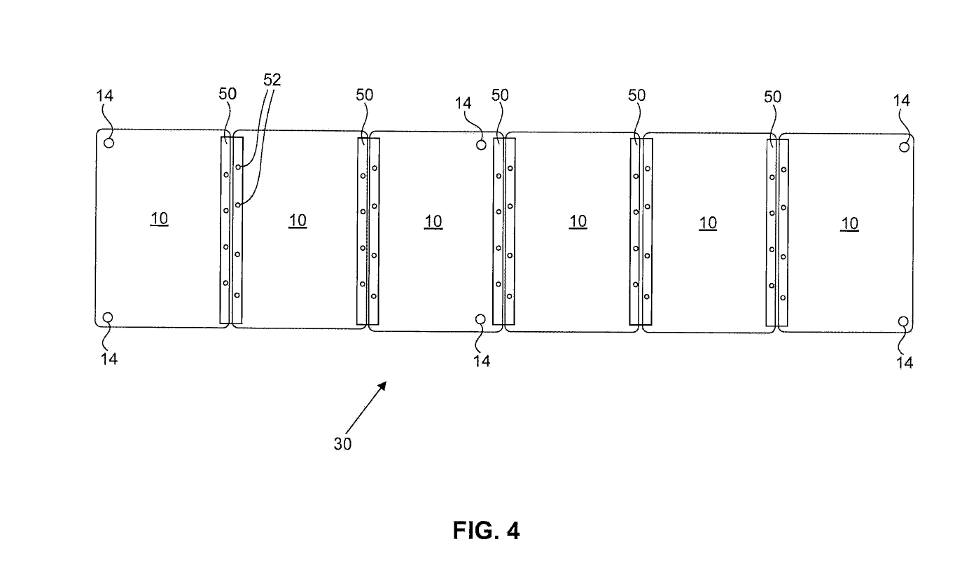

In some embodiments, a sheet 20 that accommodates the multiple solar panels 10 of a foldable array 30 and link them together may be eliminated. In some such embodiments, the solar panels 10 themselves may be linked together. For example, in one embodiment, as illustrated in FIG. 4, hinges 50 may couple the multiple solar panels 10 of a foldable array 30A together. To transform the foldable array 30A from the expanded configuration (illustrated in FIG. 4) to a collapsed configuration, the hinges 50 may be folded in an accordion-like manner as explained with reference to FIGS. 1A-1C. Although a single row of solar panels 10 are illustrated in FIG. 4, in some embodiments as described previously, the solar panels 10 may be arranged in multiple rows. Some or all of the solar panels 10 of the foldable array 30A (such as, for example, the left-most and the right-most solar panels 10) may include securing holes 14 to attach a deployed foldable array 30A to the ground. In some embodiments, each hole 14 may be reinforced with a metal ring for strength. In some embodiments, some of the center solar panels 10 may also be provided with reinforced securing holes 14.

The hinges 50 may be attached to the solar panels 10 using rivets 52 passing through mating holes or cavities of the hinges 50 and the solar panels 10. In some embodiments, as illustrated in FIG. 4, the left-most and the right-most solar panels 10 may only include a hinge 50 on one side to couple to an adjacent solar panel 10. The solar panels 10 positioned in between the left-most and right-most panels may include hinges 50 on both sides to couple to adjacent solar panels 10 on either side. However, this arrangement is only exemplary. In some embodiments, a hinge 50 may also be provided on both sides of one or both of the left-most and the right-most solar panels 10. In such an embodiment, a hinge 50 on the left side of the left-most solar panel 10 (or on the right side of the right-most solar panel 10) may couple to a cover that may fold over an exposed surface of the solar panel 10 in the collapsed configuration.

The hinges 50 may be made of any material and may have any configuration. In some embodiments, the hinges 50 may be rugged and may be suitable for sandy/muddy and hot and/or cold environments. In some embodiments (for example, in foldable arrays 30A containing smaller solar panels 10), the hinges may be made of a plastic-type material, while in other embodiments (such as, for example, in foldable arrays 30A including larger solar panels 10), the hinges may be made of a metal or a similar material. The hinges 50 may be configured in any manner (such as, for example, barrel hinge, pivot hinge, continuous or piano hinge, strap hinge, flag hinge, etc.) that can withstand repetitive bending without failure. The rivets 52 that secures a hinge 50 to a solar panel 10 may be a low-profile rivet to allow compactness when the assembly is folded. In some embodiments, as illustrated in FIG. 4, the rivets 52 may be staggered to avoid interference with each other when the foldable array is folded to the collapsed configuration.

As explained with reference to foldable array 30 of FIGS. 3A and 3B, the solar panels 10 of foldable array 30A may be electrically connected together and to the external circuitry in any known manner (for example, in series). Similar to the foldable array 30 of FIGS. 3A and 3B, the solar panels 10 may include separate positive and negative wires or connectors hardwired into the solar panels 10. These connectors may be positioned on one edge (for example, the top edge) of the solar panels 10. A positive feed-wire may also be provided at the bottom edge of the solar panels 10 to connect to the positive connector of the left-most or right-most solar panel 10. In some embodiments, the positive wire and the negative wire of adjacent solar panels 10 may be connected together through the hinge 50 between them. In such an embodiment, a hole may be drilled into the hinge 50 through which the wires may pass. The wires may be permanently connected and protected via an insulated wire connector (for example, one having a nylon sleeve and a suitable metal insert). In some embodiments, a padded material may be placed around the outside of the hinges 50 in the area of the wires to protect the wires. In some embodiments, a junction box or a connector may be provided on the back side of one of the solar panels (for example, the left-most or the right-most solar panel 10) to serve as a connection to external circuitry. As described with reference to foldable array 30 of FIGS. 1A-1C, foldable array 30A may also include securement straps and handles. These straps and handles may include Velcro-like fasteners and may be attached to the back surface of the solar panels 10 or to the hinges 50.

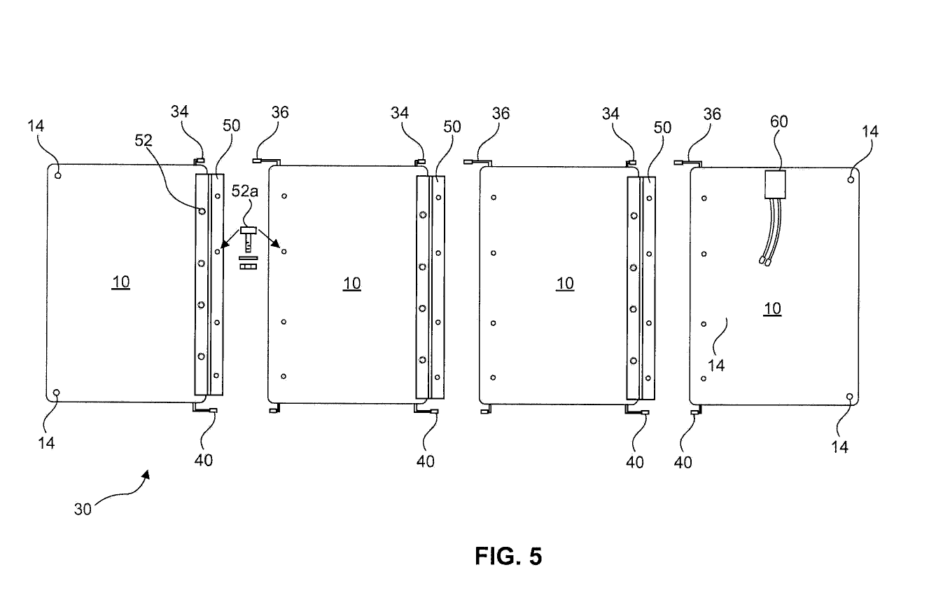

In some embodiments, the foldable array 30A may be configured such that the solar panels 10 are replaceable. FIG. 5 illustrates an embodiment in which replaceable solar panels 10 that includes a hinge 50 attached to a side thereof are coupled together to form a foldable array 30B. As illustrated in FIG. 5, hinges 50 may be attached to the right side of the solar panels 10 using rivets 52. During assembly of the solar panels 10 into folding array 30B, the hinge attachment holes in the right side of the hinge 50 will be aligned with the panel attachment holes in the left side of the solar panel 10. The solar panel 10 may then be connected to the hinge 50 using screws, bolts 52a (only one bolt 52a is illustrated in FIG. 5), Velcro, or other mechanical connection elements. To replace a defective solar panel 10, the bolt 52a may be removed to separate a solar panel 10 from its adjacent solar panel 10 and replaced. It should be noted that the disclosed mechanical connection elements are only exemplary and any other connection mechanisms known in the art may be employed to connect a replaceable solar panel 10 to a hinge 50. The solar panels 10 also includes connectors that are electrically coupled to the solar cells of the solar panel 10. During assembly of the solar panels 10, the connectors of one solar panel 10 engages with the mating connectors of an adjacent solar panel 10 to electrically connect the solar panels 10 together in a serial manner Note that, in FIG. 5, the left-most solar panel 10 and the right-most solar panel 10 are slightly different than the two middle solar panels 10 in that these middle solar panels 10 do not include securement holes 14 and include connectors on both sides. Although not shown in FIG. 5, the foldable array 30A (and other disclosed foldable arrays) may include handles, wheels, and other devices (including a skid, etc.) to enable the foldable array to be transported from one location to another.

Although the connectors may be arranged in any manner suitable to electrically couple the solar panels 10 together, in some embodiments, as illustrated in FIG. 5, a connector of one polarity is configured to mate with a connector of an opposite polarity on the top edge of an adjacent solar panel 10, when the solar panels are coupled together. In some embodiments, a positive connector 36 may be attached to the top left side of all the solar panels 10 (except the left-most solar panel 10), and a negative connector 34 may be permanently attached to top right side of each solar panel 10 (except the right-most solar panel 10). When the solar panels 10 are coupled together, the adjacent connectors couple together to connect the solar panels 10 together serially. Positive feed connectors 40 may be attached at the bottom left and right corners of all the solar panels 10 (Note that, in the embodiment of FIG. 5, the left-most solar panel 10 only has one positive feed connector 40 attached on the right side and the right-most solar panel 10 only has one positive feed connector 40 attached on the left side). A positive connector 36 may be just long enough to allow a user to easily attach the connecting portion to the corresponding negative connector 34 of the adjacent solar panel 10. The negative connector 34 may likewise be as short as possible, such that, when attached, the connectors rest close to the top edge of the solar panels 10. The connectors may be configured to snap together (for example, having a bayonet, or similar locking mechanism) when the solar panels 10 are coupled together, and may be substantially waterproof or water-resistant. In some embodiments, as illustrated in FIG. 5, the right-most solar panel 10 may include a junction box 60 and the positive feed connector 40 of the right-most solar panel 10 may be connected to the junction box 60. In such embodiments, connectors from the junction box 60 may be used to connect the foldable array 30B to external circuitry.

The disclosed portable solar panel arrays improve the efficiency of solar energy technology by allowing the solar panels to be easily moved from one location to another (for example, to follow sunlight). Since defective solar panels in an array can be easily replaced with new solar panels, the disclosed portable solar panel arrays will be more cost effective. Additionally, the ability to drape a portable solar panel array on curved and sloping surfaces (such as, for example, the roof of a tent), will enable solar energy technology to be used in applications which were not previously possible. Thus, the disclosed portable solar panel arrays of the current disclosure materially contributes to the development of renewable energy resources and the more efficient utilization of solar energy technology.

Any aspect set forth in any embodiment may be used with any other embodiment set forth herein. It will be apparent to those skilled in the art that various modifications and variations can be made in the disclosed systems and processes without departing from the scope of the invention. Other embodiments of the invention will be apparent to those skilled in the art from consideration of the specification and practice of the invention disclosed herein. It is intended that the specification and examples be considered as exemplary only. The following disclosure identifies some other exemplary embodiments.

We claim:

1. A portable assembly for supporting a plurality of solar panels, the assembly comprising:
a plurality of solar panels mechanically coupled to each other and configured to transform from an expanded configuration to a collapsed configuration, wherein each solar panel of the plurality of solar panels includes one or more solar cells, wherein the expanded configuration is a configuration in which an active surface of each solar panel of the plurality of solar panels is exposed, and the collapsed configuration is a configuration in which the active surfaces of the plurality of solar panels overlap; and
connectors configured to removably electrically connect the plurality of solar panels together.

2. The assembly of claim 1, wherein the plurality of solar panels are configured to transform from the expanded configuration to the collapsed configuration in an accordion-like manner.

3. The assembly of claim 1, wherein the plurality of solar panels are arranged side-by-side along a single row.

4. The assembly of claim 1, further including a flexible sheet that mechanically couples the plurality of solar panels together, wherein the sheet is configured to fold to transform the plurality of solar panels from the expanded configuration to a collapsed configuration.

5. The assembly of claim 4, wherein the sheet includes a plurality of pouches, wherein each pouch of the plurality of pouches is configured to accept therein a solar panel of the plurality of solar panels.

6. The assembly of claim 5, wherein the sheet includes a flap that is configured to fold over and attach to a back surface of the plurality of pouches.

7. The assembly of claim 5, wherein the sheet includes windows that are configured to expose the active surfaces of the plurality of solar panels therethrough.

8. The assembly of claim 5, wherein the sheet is configured to fold along regions between adjacent solar panels of the plurality of solar panels to transform from the expanded configuration to the collapsed configuration.

9. The assembly of claim 5, wherein the sheet includes fastening straps configured to secure the assembly in the collapsed configuration.

10. The assembly of claim 1, further including hinges positioned between adjacent solar panels of the plurality of solar panels, wherein the hinges mechanically couple the adjacent solar panels together.

11. The assembly of claim 10, wherein the plurality of solar panels are removably coupled together using the hinges and bolts.

12. The assembly of claim 1, wherein the plurality of solar panels include an even number of solar panels, and in the collapsed configuration, the active surfaces of each adjacent pair of solar panels of the plurality of solar panels face each other.

13. A method of using a portable array of solar panels including a plurality of solar panels mechanically coupled to each other, wherein each solar panel of the plurality of solar panels includes one or more solar cells, comprising:
positioning the portable array in an expanded configuration, the expanded configuration being a configuration in which the plurality of solar panels are arranged side-by-side and an active surface of each solar panel of the plurality of solar panels is exposed; and
transforming the portable array from the expanded configuration to a collapsed configuration, the collapsed configuration being a configuration in which the plurality of solar panels are stacked over each other while maintaining the mechanical coupling of the panels to one another.

14. The method of claim 13, wherein transforming the portable array from the expanded configuration to the collapsed configuration includes rolling the portable array from the expanded configuration to the collapsed configuration.

15. The method of claim 13, further including replacing a first solar panel of the plurality of solar panels with a second solar panel by mechanically decoupling the first solar panel from the portable array while maintaining the mechanical coupling of the remaining panels to one another.

16. The method of claim 15, wherein mechanically decoupling the first solar panel includes removing the first solar panel from a pouch of the portable array.

17. A portable assembly for supporting a plurality of solar panels, the assembly comprising:
a plurality of solar panels each including one or more solar cells, the plurality of solar panels including an even number of solar panels mechanically coupled together, the plurality of solar panels being configured to transform from an expanded configuration to a collapsed configuration, the expanded configuration being a configuration in which the plurality of solar panels are arranged side-by-side with an active surface of each solar panel of the plurality of solar panels exposed, and the collapsed configuration being a configuration in which the plurality of solar panels are stacked one on top of another; and
connectors that are configured to electrically couple the plurality of solar panels together.

18. The portable assembly of claim 17, wherein, in the collapsed configuration, the active surfaces of each adjacent pair of solar panels of the plurality of solar panels face each other.

19. The portable assembly of claim 17, further including a flexible sheet including a plurality of pouches, wherein each solar panel of the plurality of solar panels is positioned in a pouch of the plurality of pouches.

20. The portable assembly of claim 17, wherein each adjacent solar panel of the plurality of solar panels are mechanically coupled together with a hinge positioned therebetween.
